(19) United States
(12) Patent Application Publication
(10) Pub. No.: US 2003/0071231 A1
(43) Pub. Date: Apr. 17, 2003

(54) Electron beam exposing method and exposure apparatus

(76) Inventors: Takeshi Haraguchi, Tokyo (JP); Takamasa Satoh, Tokyo (JP)

Correspondence Address: CHRISTIE, PARKER & HALE, LLP, P.O. BOX 7068, PASADENA, CA, 91109-7068, US

(21) Appl. No.: 10/252,756

(22) Filed: Sep. 23, 2002

(30) Foreign Application Priority Data
Oct. 11, 2001 (JP) 2001-314136

(51) Int. Cl. H01J 37/304

(52) U.S. Cl. 250/492.22

(57) ABSTRACT

An electron beam exposure apparatus of high accuracy and high throughput despite a change in the ambient atmospheric pressure has been disclosed. In an electron beam exposure apparatus, and an electron beam exposing method using it, which comprises a vacuum chamber that accommodates a column and a stage and internally contains a vacuum, the atmospheric pressure in the environment, in which the electron beam apparatus is installed, is detected and the irradiation position of the electron beam on a specimen or the focal position of the electron beam with respect to the surface of the specimen is corrected according to the detected atmospheric pressure.

### BACKGROUND OF THE INVENTION

The present invention relates to an electron beam exposure apparatus. More particularly, the present invention relates to an electron beam exposure apparatus that can achieve a high-accuracy exposure despite variations in the operating environment.

There is a general trend that the density of semiconductor integrated circuits increases depending on advances in micro-machining technology, and the performance required for the micro-machining technology becomes better and better. Particularly, in exposure technology, the limit of the optical exposure technology used for devices such as a conventional stepper has been reached. Electron beam exposure technology may be used instead of the optical exposure technology for the advanced micro-machining technology and a high accurate positioning ability and a high resolving ability may be required.

There are several types of the electron beam exposure apparatuses such as the single stroke type, the variable rectangle exposure type, the block exposure type, and the multibeam exposure type. The present invention can be applied to any type and description is made with examples of the block exposure type electron beam exposure apparatus, but the present invention is not limited to these.

FIG. 1 is a diagram that shows the rough structure of a block exposure type electron beam exposure apparatus. Reference number 1 refers to a vacuum chamber and in the vacuum chamber 1, a column composed of an electron gun 11, electromagnetic lenses (coils) 2, 3, and 6, a sub deflector 5, a main deflector 7, a block mask 4, and so forth, a stage 8 that holds a specimen (wafer) 100 and moves, a detector 10 that detects reflected electrons and the secondary electrons, and so forth, are provided. A laser range finder 9 measures accurately the amount of movement of the stage 8. An actual structure is far more complicated as plural electromagnetic lenses collaborate in serving as a single electromagnetic lens, and so forth, as will be described later, but only typical functional elements are shown here. For example, the block mask 4 is composed of a mask that has plural mask units, a mask deflector that selects a mask unit for exposure, and so forth, but it is shown as a single unit here.

Reference number 41 refers to an exposure control circuit that generates a deflection signal of the block mask 4, a sub deflector signal, and a main deflector signal. Although not shown schematically here, the exposure control circuit 41 is designed so as to be able to adjust the focal position of an electron beam by varying the drive signal of the electromagnetic lens for convergence and also to generate such a signal, but a description of this is omitted here. The deflection signal to select a pattern of the block mask 4 is supplied to the deflector of the block mask 4 via a drive circuit 42. After converted into analog signals in a DAC 43 and in a DAC 45, respectively, the sub deflection signal and the main deflection signal are applied to the sub deflector 5 and the main deflector 7 via drive circuits 44 and 46. After processed in a detection circuit 47, the output of the detector 10 is put out to a total control circuit via an interface circuit. From the total control circuit, the data that supports the amount of movement of the stage is supplied to the stage control circuit 48, and the stage control circuit 48 controls the operations of the stage movement mechanism based on the data.

FIG. 2 is a diagram that shows the detailed structure inside the column. In FIG. 2, reference number 12 refers to a first convergent lens that forms the electron beam from the electron gun 11 into a parallel beam, 13 to an aperture that shapes the parallel beam passing through into a specified shape, 14 to a second convergent lens that converges the shaped beam, 15 to a deflector for shaping, 16 to a first mask deflector, 17 to a deflector that dynamically corrects the astigmatism of a mask, 18 to a second mask deflector, 19 to a convergent coil for mask, 20 to a first shaping lens, 22 to a second shaping lens, 23 to a third mask deflector, 24 to a blanking deflector for on/off control of the beam, 25 to a fourth mask deflector, 26 to a third lens, 27 to a circular aperture, 28 to a reducing lens, 29 to a focus coil, 30 to a projection lens, 31 to an electromagnetic main deflector, and reference number 32 refers to an electrostatic sub deflector.

A general electron beam exposure apparatus is described above, and a further description is omitted here as the electron beam exposure apparatus is widely known.

There is a phenomenon called drift in which the beam irradiation position and a state of convergence gradually change, and the drift degrades the exposure position accuracy of a pattern and the sharpness of a pattern. Because of this, a calibration that detects and corrects the shift in position of the beam and the state of convergence (focal point) is carried out periodically in the case of the electron beam exposure apparatus. For example, the shift in deflection position is detected by detecting with a detector the reflected electron when a reference mark on a specimen is scanned to detect the position of the reference mark and by calculating the difference between the detected position of the reference mark and the current deflection position. The shift in deflection position is corrected by adding a signal in the shift-correcting direction to the signal bound for the deflector. The beam focus is detected as a most optimum point that corresponds to the case where the change in signal detected by the detector is sharpest when scanning the reference mark while changing the current of the focus coil to change the focal position. The calibration is carried out periodically and the corrected condition is maintained until the next calibration.

Since exposure cannot be carried out during calibration, the throughput is lowered accordingly. Therefore, it is preferable that the interval between calibrations is as long as possible. During the interval between calibrations, however, the corrected amount is maintained and if the shift in position or the change in focus is large in the period, a problem occurs in that the accuracy of exposure position and the sharpness of a pattern are degraded accordingly. In other words, the interval between calibrations and the accuracy and throughput are closely related.

As described above, the electron beam exposure apparatus is characterized by its ability to expose a pattern as fine as 0.1 μm or less, and may be used for future micro-machining technology. Recently, in particular, it is expected to be a technology to realize nano-technology and the requirements for the exposure position accuracy and the sharpness of a pattern become more and more severe. Because of this, it is necessary to reduce the intervals between calibrations but, if this is done, the throughput is lowered.

### SUMMARY OF THE INVENTION

The objective of the present invention is to improve throughput by lengthening the interval between calibrations without degrading the exposure position accuracy and the sharpness of a pattern of the electron beam exposure apparatus.

In order to achieve the above-mentioned objective, the change in the atmospheric pressure in the environment in which an apparatus, which causes the shift in beam irradiation position and that in focus to occur, is installed is detected all the time and the shift generated in the intervals between calibrations is reduced by correcting it in real time in the present invention.

In other words, the electron beam exposure apparatus and the exposing method of the present invention comprises a column that has a beam source, a convergent means that converges the electron beam onto a specimen, and a deflection means that deflects the electron beam, a stage that holds the specimen and moves, and a vacuum chamber that contains the column and the stage internally and also contains a vacuum internally, wherein the atmospheric pressure in the environment in which the electron beam exposure apparatus is installed is detected and the irradiation position of the electron beam on the specimen and the focal point of the electron beam with respect to the surface of the specimen are corrected according to the detected atmospheric pressure.

FIG. 3A and FIG. 3B are diagrams that illustrate the principles of the present invention, wherein FIG. 3A shows the side view and FIG. 3B shows the top view. In the beam electron exposure apparatus, the vacuum chamber 1 is manufactured so as to have enough rigidity because the inside of the vacuum chamber 1 that contains the column and the stage 8 is brought into a state of vacuum. When the inside of the vacuum chamber 1 is made to contain a vacuum, a considerable force is exerted on the walls of the vacuum chamber 1. For example, as the size of the main chamber of the electron beam exposure apparatus is approximately a meter square, the force exerted to the walls by the atmospheric pressure is approximately 10 tons at 1 atmospheric pressure (approximately 1,000 hPa), and if the atmospheric pressure changes by 1 hPa, the force exerted to the walls changes by approximately 10 kg. Although it depends on the materials and thickness of the walls of the chamber, the amount of distortion changes by approximately 0.01 to 1 μm when the force exerted to the walls changes by 10 kg.

Changes in atmospheric pressure during the intervals between calibrations have been regarded as negligible, and the influence has been ignored and no special countermeasure has been taken so far. For an apparatus, however, which can realize nano-technology, such an amount of change cannot be ignored because of the requirement of an accuracy of the order of a nanometer. The present applicants have focused their attention on the fact that the shift generated in the intervals between calibrations can be suppressed by continuously detecting the changes in atmospheric pressure in the operating environment of the apparatus and by correcting the shifts in the beam irradiation position and focal point caused by the changes.

It is thought that the vacuum chamber 1 is distorted as shown in FIG. 3A and FIG. 3B when pressed by the atmospheric pressure. The distortions of the upper surface and the lower surface of the chamber cause the column to change its position in the vertical direction with respect to the stage surface and the convergent point (focus) of the beam is shifted in the direction of the optical axis. An X-direction length measuring device 51 and a Y-direction length measuring device 53 are provided on the sides of the chamber, as shown in FIG. 3B, and the changes in distance between a reflection mirror 52 fixed to the movable stage 8 and the X-direction length measuring device 53 and between a reflection mirror 55 fixed to the movable stage 8 and the Y-direction length measuring device 55 are detected. When the sides are distorted by the changes in the atmospheric pressure, the length measuring devices move in the X direction and in the Y direction, respectively, and a drift in position in each direction is caused to occur. The change in the atmospheric pressure is within 5% per 1 atmospheric pressure, and within this range, it is possible to assume that the shift in position in the X direction and Y direction and the shift in focal point in the direction of the optical axis are in proportion to the amount of change in the atmospheric pressure. The amount of shift in each direction, therefore, generated by the changes in the atmospheric pressure is investigated in advance by experiments in order to determine the correction factors, and correction is made accordingly using the correction value calculated by multiplying the factor by the detected amount of change in the atmospheric pressure.

It is easiest to correct the shifts in X and Y direction by varying the amount of beam deflection by the correction value. However, it is possible to vary the X and Y coordinates of the stage by the correction value. It is easiest to correct the shift in focal position by varying the current of the focus coil. However, it is possible to vary the Z coordinates of the stage by the correction value.

The correction factor is determined by the simulation based on the structural data of the vacuum chamber, or determined by measuring the shift in deflection position and that in focal position of the beam on the specimen while actually measuring the changes in the atmospheric pressure in the environment in which the apparatus is installed.

When the correction circuit is composed using analog circuits, it is composed of a circuit that calculates the difference between the output of a barometer 61 and the reference atmospheric pressure value and an amplifier that amplifies the output, and the output of the amplifier is added to the deflection signal put out by the deflection amplifier. In this case, the gain of the amplifier corresponds to the correction factor and it is necessary to adjust the gain according to the correction factor. Since it is difficult to adjust the gain when the amount of change in the atmospheric pressure detected by the barometer is small, the gain of the amplifier is adjusted by entering a signal value corresponding to the atmospheric pressure value that has considerably changed (for example, an atmospheric pressure value that has changed by 300 hPa) instead of the detected signal of the barometer, so that the current deflection position and the focal position of the beam on the specimen are shifted by the amount that is the product of the correction factor and the signal value.

### BRIEF DESCRIPTION OF THE DRAWINGS

The features and advantages of the present invention will be more clearly understood from the following description taken in conjunction with accompanying drawings, in which:

FIG. 1 is a block diagram that shows the rough structure of the conventional electron beam exposure apparatus.

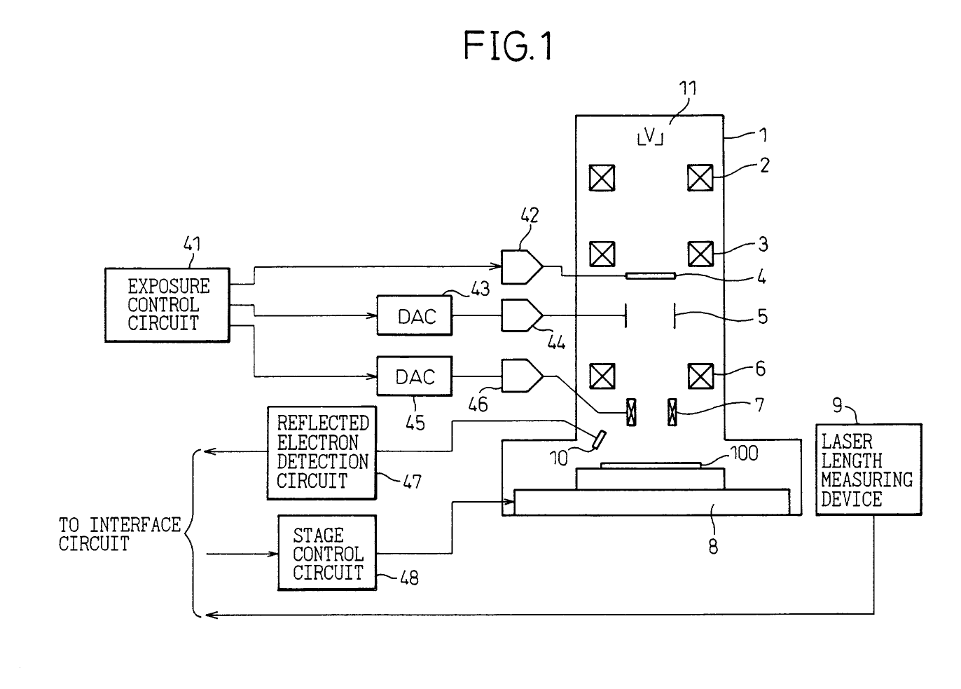

FIG. 2 is a diagram that shows the column structure of the conventional electron beam exposure apparatus.

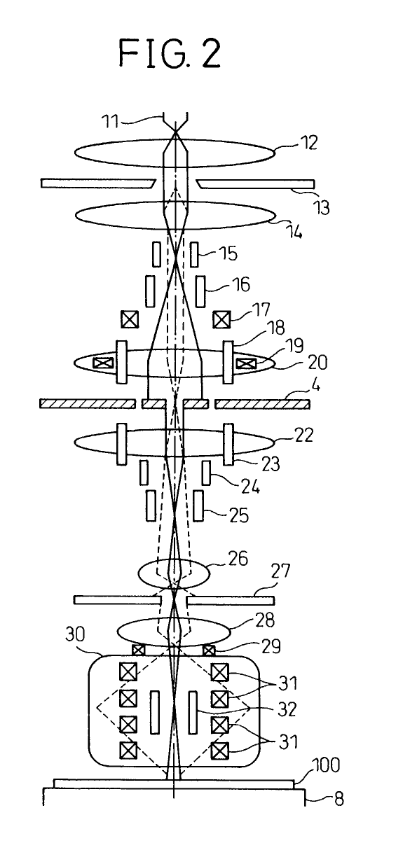

FIG. 3A and FIG. 3B are diagrams that illustrate the influence due to the changes in the atmospheric pressure in the environment in which the apparatus is accommodated.

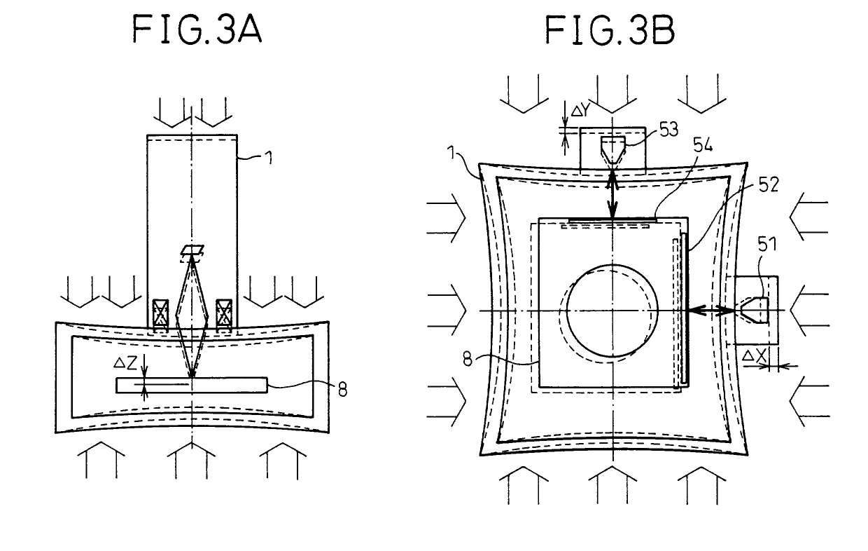

FIG. 4 is a block diagram that shows the structure of the electron beam exposure apparatus in the first embodiment of the present invention.

FIG. 5 is a block diagram that shows the structure of the electron beam exposure apparatus in the second embodiment of the present invention.

### DESCRIPTION OF THE PREFERRED EMBODIMENTS

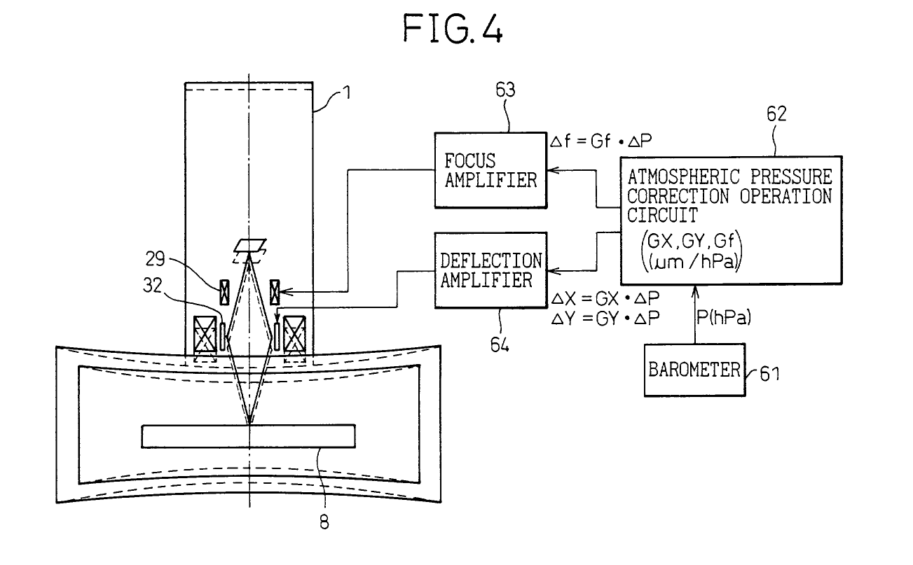

FIG. 4 is a diagram that shows the structure of the electron beam exposure apparatus in the first embodiment of the present invention. The structure of the inside of the vacuum chamber 1 is the same as the conventional one and, as shown schematically, the focus coil 29, the electrostatic deflector 32 that corresponds to the sub deflector, and the stage 8 are also provided similarly. Moreover, a focus amplifier 63 that applies the drive signal to the focus coil 29 and a deflection amplifier 64 that applies the drive signal to the electrostatic deflector 32 are also provided similarly. The focus amplifier 63 changes the drive signal so as to correct the difference in focal position that corresponds to the difference in Coulomb interaction due to the difference in intensity of the electron beam through the exposure pattern as well as changing the drive signal according to the periodic calibrations. The deflection amplifier 64 changes the drive signal according to the exposure position of the beam in the range of the sub-deflection.

In addition to the conventional structure described above, the electron beam exposure apparatus in the first embodiment comprises the barometer 61 and an atmospheric pressure correction operation circuit 62. The barometer 61 detects the atmospheric pressure in the environment in which the electron beam exposure apparatus is installed, and sends the value P of the continuously detected atmospheric pressure (hPa) to the atmospheric pressure correction operation circuit 62. The atmospheric pressure correction operation circuit 62 stores the correction factors GX, GY, and Gf, and calculates the values GX·ΔP, GY·ΔP, and Gf·ΔP by multiplying the change in the atmospheric pressure ΔP by the correction factors GX, GY, and Gf, respectively. GX·ΔP is the correction value in the X direction of the deflection amplifier 64, GY·ΔP is the correction value in the Y direction of the deflection amplifier 64, and Gf·ΔP is the correction value of the focus coil 63. The deflection amplifier 64 adds GX·ΔP and GY·ΔP to the drive signals in the X direction and in the Y direction, respectively. By this, the position of the beam is corrected. The focus coil 63 adds Gf·ΔP to the drive signal. By this, the focal position is corrected. Although the atmospheric pressure correction operation circuit 62 can be realized using digital operation circuits, the actual one is made up of an analog circuit that calculates the difference between the output of the barometer 61 and the reference atmospheric pressure value and an amplifier that amplifies the output so that the gain of the amplifier corresponds to the correction factor.

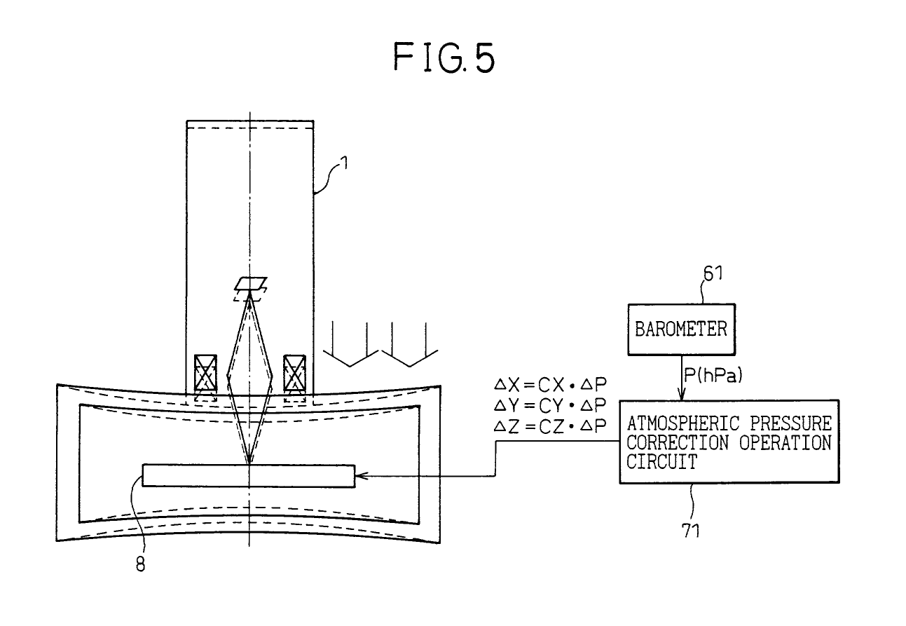

FIG. 5 is a diagram that shows the structure of the electron beam exposure apparatus in the second embodiment of the present invention. The second embodiment differs from the first embodiment in that the shift due to the change in the atmospheric pressure is corrected using the coordinates of the stage 8. An atmospheric pressure correction operation circuit 71 stores the correction factors CX, CY, and CZ to correct the coordinates of the stage, calculates the values CX·ΔP, CY·ΔP, and CZ·ΔP by multiplying the change in the atmospheric pressure ΔP by the correction factors CX, CY, and CZ, respectively, and sends them to the stage control circuit. The stage control circuit changes the coordinates by the correction value. By this, the position of beam and the focal position are corrected.

The correction factors used in the first and the second embodiments are determined by the simulation based on the structural data of the vacuum chamber or determined by measuring the shift in deflection position and that in focal position of the beam on the specimen while actually measuring the change in the atmospheric pressure in the environment in which the apparatus is installed.

The gain of the amplifier of the atmospheric pressure correction operation circuit is set according to the correction factor determined as described above but, if the amount of change in the atmospheric pressure detected by the barometer is small, it is difficult to set the gain. Instead of the detection signal of the barometer, therefore, a signal value that corresponds to the atmospheric pressure value that has considerably changed (for example, the atmospheric pressure valued that has changed by 300 hPa) is entered and the gain of the amplifier is set so that the current deflection position and the focal position of the beam on the specimen are shifted by the amount that corresponds to the correction factor multiplied by the signal value.

According to the present invention, as described above, the intervals between calibrations can be lengthened without degrading the exposure position accuracy and the sharpness of a pattern of the electron beam exposure apparatus, and the electron beam exposure apparatus of high accuracy and high throughput can be realized.

We claim:

1. An electron beam exposing method using an electron beam exposure apparatus comprising: a column that has a beam source to produce an electron beam; a convergent means to converge the electron beam onto a specimen; a deflection means to deflect the electron beam; a stage that holds the specimen and moves; and a vacuum chamber that internally accommodates the column and the stage and internally contains a vacuum, wherein the atmospheric pressure in the environment, in which the electron beam exposure apparatus is installed, is detected and the irradiation position of the electron beam on the specimen is corrected according to the detected atmospheric pressure.

2. An electron beam exposing method, as set forth in claim 1, wherein the focal position of the electron beam with respect to the surface of the specimen is corrected according to the detected atmospheric pressure.

3. An electron beam exposing method, as set forth in claim 1, wherein the irradiation position of the electron beam on the specimen is corrected by adding the amount of change in the atmospheric pressure multiplied by the position correction factor to the amount of deflection by the deflection means.

4. An electron beam exposing method, as set forth in claim 2, wherein the irradiation position of the electron beam on the specimen is corrected by adding the amount of change in the atmospheric pressure multiplied by the position correction factor to the amount of deflection by the deflection means.

5. An electron beam exposing method, as set forth in claim 3, wherein the amount of deflection by the deflection means is specified by the rectangular coordinates in a plane parallel to the surface of the specimen and the position correction factor is determined for each pair of two coordinate axes of the rectangular coordinates.

6. An electron beam exposing method, as set forth in claim 4, wherein the amount of deflection by the deflection means is specified by the rectangular coordinates in a plane parallel to the surface of the specimen and the position correction factor is determined for each pair of two coordinate axes of the rectangular coordinates.

7. An electron beam exposing method, as set forth in claim 3, wherein the process to multiply the amount of change in the atmospheric pressure by the position correction factor is carried out by amplifying the amount of change in the atmospheric pressure using the gain that corresponds to the position correction factor and the setting of the gain is carried out, in a state in which a large amount of change in the atmospheric pressure is entered, by adjusting so that the irradiation position of the electron beam on the specimen is shifted by the amount corresponding to the large amount of change in the atmospheric pressure multiplied by the position correction factor.

8. An electron beam exposing method, as set forth in claim 4, wherein the process to multiply the amount of change in the atmospheric pressure by the position correction factor is carried out by amplifying the amount of change in the atmospheric pressure using the gain that corresponds to the position correction factor and the setting of the gain is carried out, in a state in which a large amount of change in the atmospheric pressure is entered, by adjusting so that the irradiation position of the electron beam on the specimen is shifted by the amount corresponding to the large amount of change in the atmospheric pressure multiplied by the position correction factor.

9. An electron beam exposing method, as set forth in claim 5, wherein the process, to multiply the amount of change in the atmospheric pressure by the position correction factor, is carried out by amplifying the amount of change in the atmospheric pressure using the gain that corresponds to the position correction factor and the setting of the gain is carried out, in a state in which a large amount of change in the atmospheric pressure is entered, by adjusting so that the irradiation position of the electron beam on the specimen is shifted by the amount corresponding to the large amount of change in the atmospheric pressure multiplied by the position correction factor.

10. An electron beam exposing method, as set forth in claim 6, wherein the process to multiply the amount of change in the atmospheric pressure by the position correction factor is carried out by amplifying the amount of change in the atmospheric pressure using the gain that corresponds to the position correction factor and the setting of the gain is carried out, in a state in which a large amount of change in the atmospheric pressure is entered, by adjusting so that the irradiation position of the electron beam on the specimen is shifted by the amount corresponding to the large amount of change in the atmospheric pressure multiplied by the position correction factor.

11. An electron beam exposing method, as set forth in claim 2, wherein the focal position of the electron beam with respect to the surface of the specimen is corrected by adding the amount of change in the atmospheric pressure multiplied by the focal position correction factor to the amount of focal position correction by the convergent means.

12. An electron beam exposing method, as set forth in claim 11, wherein the process to multiply the amount of change in the atmospheric pressure by the focal position correction factor is carried out by amplifying the amount of change in the atmospheric pressure using the gain that corresponds to the focal position correction factor and the setting of the gain is carried out, in a state in which a large amount of change in the atmospheric pressure is entered, by adjusting so that the focal position of the electron beam with respect to the surface of the specimen is shifted by the amount corresponding to the large amount of change in the atmospheric pressure multiplied by the focal position correction factor.

13. An electron beam exposing method, as set forth in claim 1, wherein the irradiation position of the electron beam on the specimen is corrected by varying the coordinates of the stage for each pair of two coordinate axes of the rectangular coordinates in a plane parallel to the surface of the specimen by the amount of that of change in the atmospheric pressure multiplied by the position correction factor.

14. An electron beam exposing method, as set forth in claim 2, wherein the irradiation position of the electron beam on the specimen is corrected by varying the coordinates of the stage for each pair of two coordinate axes of the rectangular coordinates in a plane parallel to the surface of the specimen by the amount of that of change in the atmospheric pressure multiplied by the position correction factor.

15. An electron beam exposing method, as set forth in claim 2, wherein the focal position of the electron beam with respect to the surface of the specimen is corrected by varying the coordinates of the stage in a direction perpendicular to a plane parallel to the surface of the specimen by the amount of that of change in the atmospheric pressure multiplied by the focal position correction factor.

16. An electron beam exposing method using an electron beam exposure apparatus comprising: a column that has a beam source to produce an electron beam; a convergent means to converge the electron beam onto a specimen; a deflection means to deflect the electron beam; a stage that holds the specimen and moves; and a vacuum chamber that internally accommodates the column and the stage and internally contains a vacuum, wherein the atmospheric pressure in the environment, in which the electron beam exposure apparatus is installed, is detected and the focal position of the electron beam with respect to the surface of the specimen is corrected according to the detected atmospheric pressure.

17. An electron beam exposing method, as set forth in claim 16, wherein the focal position of the electron beam with respect to the surface of the specimen is corrected by adding the amount of change in the atmospheric pressure multiplied by the focal position correction factor to the amount of focal position correction by the convergent means.

18. An electron beam exposing method, as set forth in claim 17, wherein the process to multiply the amount of change in the atmospheric pressure by the focal position correction factor is carried out by amplifying the amount of change in the atmospheric pressure using the gain that corresponds to the focal position correction factor and the setting of the gain is carried out, in a state in which a large amount of change in the atmospheric pressure is entered, by adjusting so that the focal position of the electron beam with respect to the surface of the specimen is shifted by the amount corresponding to the large amount of change in the atmospheric pressure multiplied by the focal position correction factor.

19. An electron beam exposing method, as set forth in claim 16, wherein the focal position of the electron beam with respect to the surface of the specimen is corrected by varying the coordinates of the stage in a direction perpendicular to a plane parallel to the surface of the specimen by the amount of that of change in the atmospheric pressure multiplied by the focal position correction factor.

20. An electron beam exposure apparatus comprising: a column that has a beam source to produce an electron beam; a convergent means to converge the electron beam onto a specimen; a deflection means to deflect the electron beam; a stage that holds the specimen and moves; a vacuum chamber that internally accommodates the column and the stage and internally contains a vacuum, a barometer that detects the atmospheric pressure in the environment, in which the electron beam exposure apparatus is installed; and a position correction means that corrects the irradiation position of the electron beam on the specimen according to the detected atmospheric pressure.

21. An electron beam exposure apparatus comprising: a column that has a beam source to produce an electron beam; a convergent means to converge the electron beam onto a specimen; a deflection means to deflect the electron beam; a stage that holds the specimen and moves; a vacuum chamber that internally accommodates the column and the stage and internally contains a vacuum; a barometer that detects the atmospheric pressure in the environment, in which the electron beam exposure apparatus is installed; and a focal position correction means that corrects the focal position of the electron beam with respect to the surface of the specimen according to the detected atmospheric pressure.

22. An electron beam exposure apparatus comprising: a column that has a beam source to produce an electron beam; a convergent means to converge the electron beam onto a specimen; a deflection means to deflect the electron beam; a stage that holds the specimen and moves; a vacuum chamber that internally accommodates the column and the stage and internally contains a vacuum; a barometer that detects the atmospheric pressure in the environment, in which the electron beam exposure apparatus is installed; and an atmospheric pressure correction operation circuit that calculates a correction value of a signal to be supplied to the deflection means to correct the irradiation position of the electron beam on the specimen and a correction value of a signal to be supplied to the convergent means to correct the focal position of the electron beam with respect to the surface of the specimen according to the detected atmospheric pressure.
